(19) United States
(12) Patent Application Publication
(10) Pub. No.: US 2005/0077535 A1
(43) Pub. Date: Apr. 14, 2005

(54) LED and its manufacturing process

(75) Inventor: Jui-Tuan Li, Taipei City (TW)

Correspondence Address: BACON & THOMAS, PLLC, 625 SLATERS LANE, FOURTH FLOOR, ALEXANDRIA, VA, 22314, US

(73) Assignee: JOINSCAN ELECTRONICS CO., LTD, Taipei Hsien (TW)

(21) Appl. No.: 10/680,092

(22) Filed: Oct. 8, 2003

(51) Int. Cl. H01L 29/22

(52) U.S. Cl. 257/100

(57) ABSTRACT

A LED manufacturing process includes multiple compounding potting procedures to form a fluorescent layer between a first resin layer and a second resin layer, keeping the chip and the electrode wire embedded with a part of the frame in the second resin layer and spaced from the fluorescent layer at a distance.

### BACKGROUND OF THE INVENTION

1. Field of the Invention

The present invention relates to light emitting diodes and, more particularly, to such a LED, in which the packing layer, which encapsulates the chip at the first leg of the frame of the LED and the electrode wire between the chip and the second leg of the frame, comprises a first resin layer, a second resin layer, and a fluorescent layer of a variety of colors sandwiched in between the first resin layer and the second resin layer.

2. Description of the Related Art

Following fast development of high technology electronic information industry, various value-added electronic apparatus have been continuously developed to serve human beings, improving the living of human beings. Regular electronic devices contain a variety electronic components including resistors, capacitors, transistors, connectors, circuit boards, chips, and LEDs (light emitting diodes). LEDs are also intensively used in flashing lights, decorative lighting fixtures, and traffic signal lights.

Regular LEDS have different colors including red, yellow, green, and blue. In order to provide a different color, for example, white, pink, or purple, a LED may be coated with a fluorescent material to change the color of the light. There are known white LEDs made by coating or electroplating an ultraviolet LED chip with a fluorescent power compound containing fluorescent powders of red, green and blue colors.

FIGS. 5 and 6 illustrates a LED manufacturing flow and is a series of schematic drawings showing the formation of a LED according to the prior art. According to this design, the LED manufacturing process includes the steps of (a) preparing a LED frame A1, (b) bonding a LED chip A2 to one leg of the LED frame A1, (c) connecting an electrode wire A3 between the LED chip A2 and the other leg of the LED frame A1, (d) molding a resin layer A4 on the LED chip A2, (e) molding a fluorescent layer A5 on the resin layer A4, (f) potting a 100% resin compound A61 in the cavity of a mold A6, (g) inserting the LED frame A1 in the resin compound A61, (h) removing the molding from the mold A6 when hardened, and (i) cutting off the excessive material strip All from the LED frame A1.

The aforesaid LED manufacturing process has numerous drawbacks as outlined hereinafter:

1. The fluorescent layer may flow on the resin layer before hardening, thereby causing solid matters to settle to the bottom of the fluorescent layer.

2. Uneven coating of the fluorescent layer or uneven formation of the resin layer on the fluorescent layer tends to occur, resulting in poor lighting of white color.

3. Because the fluorescent layer receives heat from the chip directly, it fades quickly with the use of the LED.

4. Because the fluorescent layer is directly covered on the chip, no sufficient space is provided for enabling the colors of the fluorescent layer to be well mixed, resulting in a poor lighting effect.

Therefore, it is desirable to provide a LED manufacturing process that eliminates the aforesaid drawbacks.

### SUMMARY OF THE INVENTION

The present invention has been accomplished under the circumstances in view. According to one aspect of the present invention, the LED manufacturing process includes multiple compounding potting procedures to form a fluorescent layer between a first resin layer and a second resin layer, keeping the chip and the electrode wire embedded with a part of the frame in the second resin layer. According to another aspect of the present invention, the chip is embedded in the second resin layer and spaced from the fluorescent layer at a distance, so that the colors of the fluorescent layer are well mixed to produce a stable light source after connection of the LED to power source. According to still another aspect of the present invention, the fluorescent materials for the fluorescent layer include fluorescent powders or chips of yellow, pin, red, green, and blue colors. According to still another aspect of the present invention, because the fluorescent layer is spaced from the chip at a distance, the material properties of the fluorescent layer are maintained for long without causing a fading problem.

### BRIEF DESCRIPTION OF THE DRAWINGS

FIG. 1 illustrates a LED manufacturing flow according to the first embodiment of the present invention.

FIG. 2 is a series of schematic drawings showing the formation of a LED according to the first embodiment of the present invention.

FIG. 3 is a perspective view of a LED made according to the first embodiment of the present invention.

FIG. 4 is a series of schematic drawings showings the formation of a LED according to the second embodiment of the present invention.

FIG. 5 illustrates a LED manufacturing flow according to the prior arts.

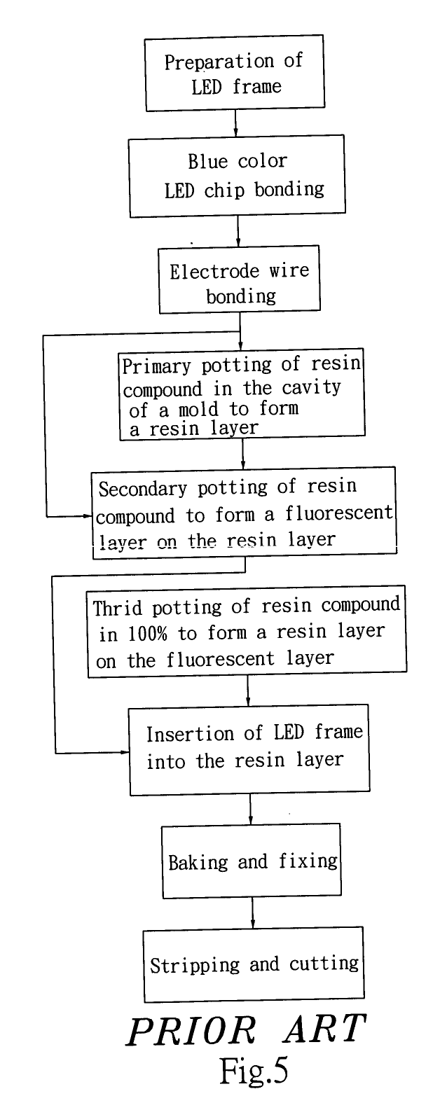

FIG. 6 is a series of schematic drawings showing the formation of a LED according to the prior art.

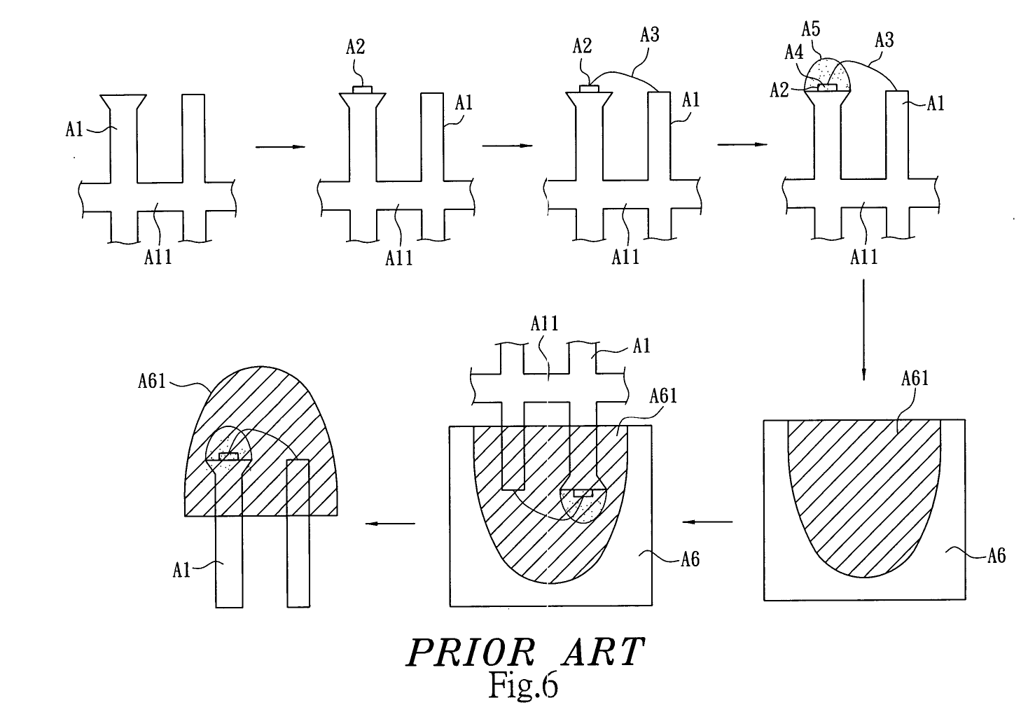

### DETAILED DESCRIPTION OF THE PREFERRED EMBODIMENT

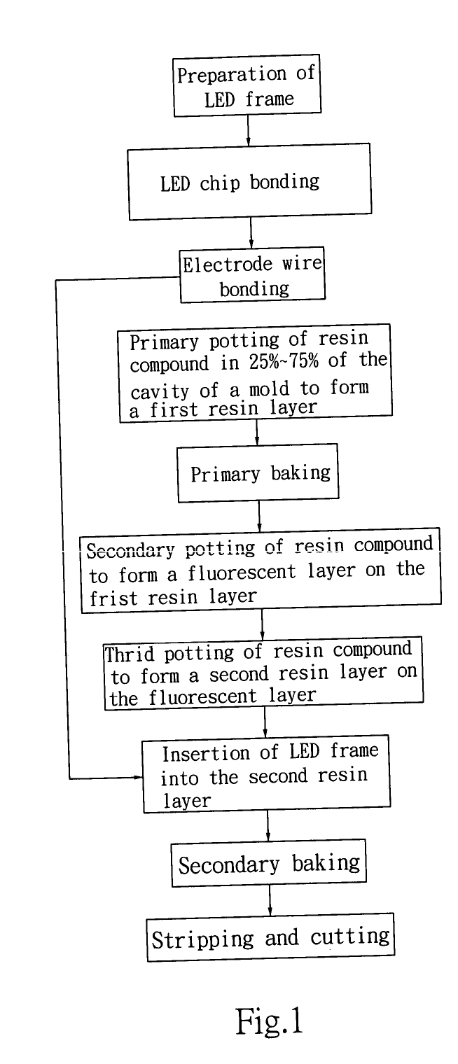

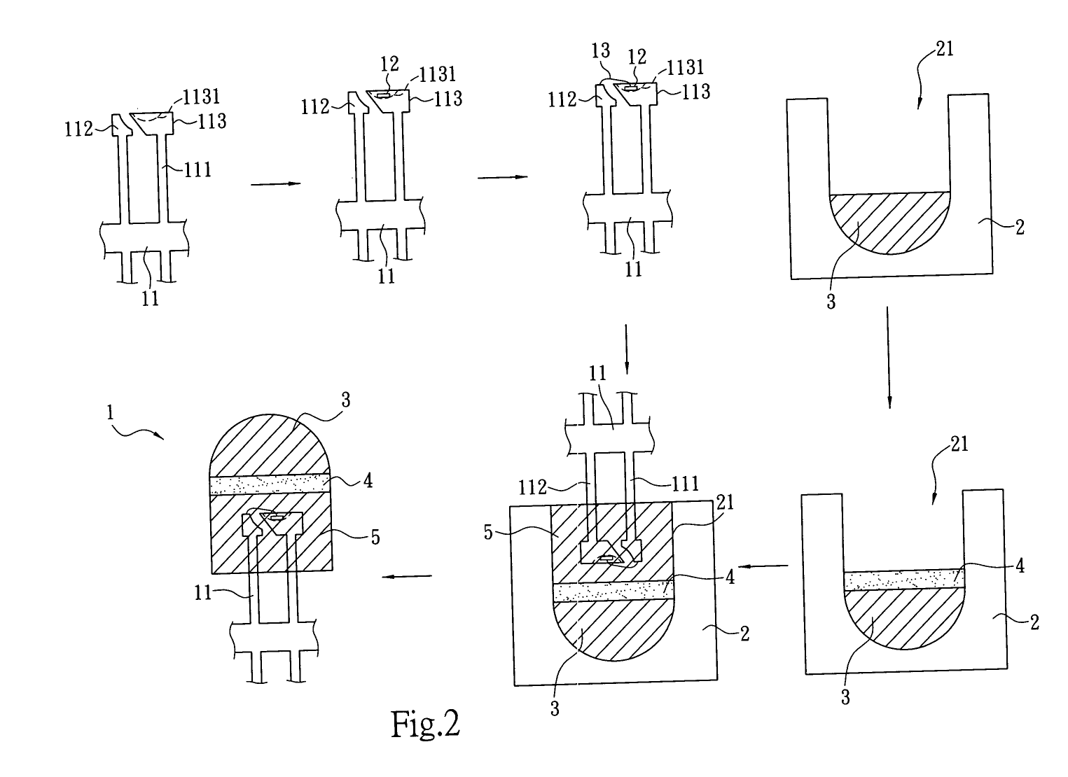

Referring to FIGS. 1 and 2, the fabrication of a LED 1 in accordance with the present invention includes a frame processing process, which comprises the steps of preparing a frame 11 having a first leg 111 and a second leg 112, bonding a chip 12 to the first leg 111, and soldering an electrode wire 13 between the chip 12 and the second leg 112.

After the aforesaid frame processing process, it proceeds to the step of primary compound potting where a compound is potted into the cavity 21 of a mold 2 to form a first resin layer 3 in about 25%˜75% of the cavity 21 of the mold 2, and then the step of primary baking to harden the first resin layer 3 in the cavity 21, and then the step of secondary compound potting where a resin compound containing fluorescent materials is potted into the cavity 21 of the mold 2 to form a fluorescent layer 4 on the first resin layer 3, and then the step of third compound potting after hardening of the fluorescent layer 4 where a resin compound is potted into the cavity 21 of the mold 2 to form a second resin layer 5 on the fluorescent layer 4 and the aforesaid frame 11 is inserted into the second resin layer 5 before hardening of the second resin layer 5 to have the chip 12 and the electrode wire 13 embedded in the second resin layer 5, and then the step of secondary baking to harden the second resin layer 5, keeping the frame 11 fixedly secured to the second resin layer 5, and then the step of stripping where the LED 1 thus formed is removed from the mold 2 and the excessive material part of the frame 11 is cut off.

The aforesaid fluorescent materials for the fluorescent layer 4 can be fluorescent powder or fluorescent chips having different colors including yellow, pink, red, green, and blue. The chip 12 of the LED 1 produces a light source when electrically connected, thereby causing the fluorescent layer 4 to emit a predetermined color of light.

As indicated above, the fluorescent materials for fluorescent layer 4 are evenly potted into the cavity 21 of the mold 2 after the formation of the first resin layer 3. After the formation of the fluorescent layer 4 on the first resin layer 3, the aforesaid third compound potting is proceeded to form a second resin layer 5 on the fluorescent layer 4, keeping the fluorescent layer 4 sandwiched in between the first resin layer 3 and the second resin layer 5.

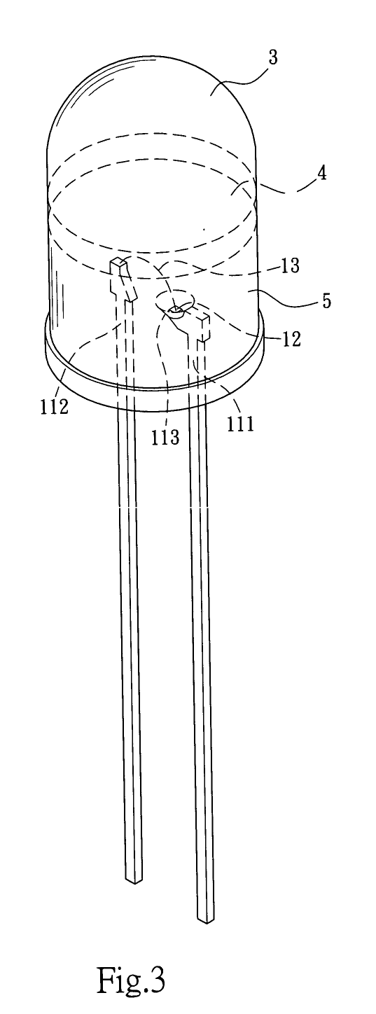

Referring to FIG. 3, the first leg 111 is terminating in a cup-like receptacle 113, which defines a receiving chamber 1131, which accommodates the chip 12. Therefore, the chip 12 can be firmly bonded to the first leg 111.

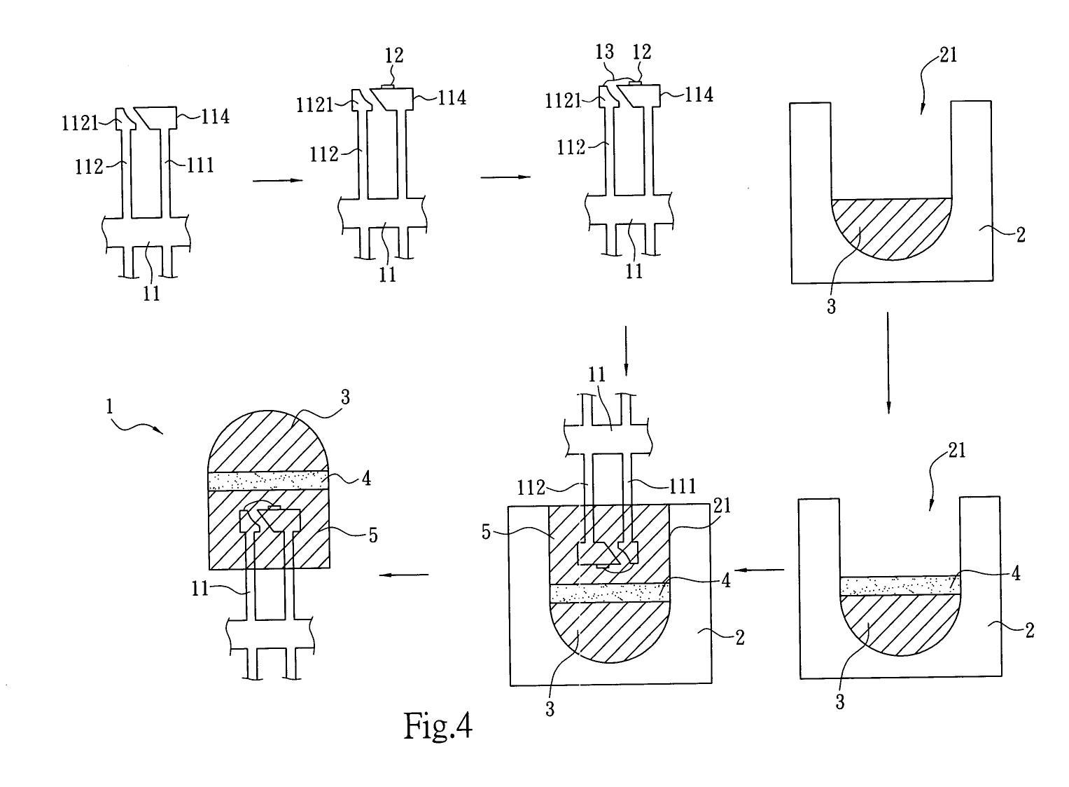

FIG. 4 is a series of schematic drawings showing the formation of a LED according to the second embodiment of the present invention. According to this embodiment, the first leg 111 of the frame 11 has a bonding endpiece 114 for the bonding of the chip 12, and the second leg 112 of the frame 11 has a soldering endpiece 1121. The electrode wire 13 is connected between the ship 12 at the bonding endpiece 114 of the first leg 111 and the soldering endpiece 1121 of the second leg 112. After preparation of the frame 11, it proceeds to the step of primary compound potting where a resin compound is potted into the cavity 21 of a mold 2 and baked to a hardened status to form a first resin layer 3 in the cavity 21 of the mold 2, and then the step of secondary compound potting where a resin compound containing fluorescent materials is potted into the cavity 21 of the mold 2 to form a fluorescent layer 4 on the first resin layer 3, and then the step of third compound potting after hardening of the fluorescent layer 4 where a resin compound is potted into the cavity 21 of the mold 2 to form a second resin layer 5 on the fluorescent layer 4 and the aforesaid frame 11 is inserted into the second resin layer 5 before hardening of the second resin layer 5 to have the chip 12 and the electrode wire 13 embedded in the second resin layer 5, and then the step of secondary baking to harden the second resin layer 5, keeping the frame 11 fixedly secured to the second resin layer 5, and then the step of stripping where the LED 1 thus formed is removed from the mold 2 and the excessive material part of the frame 11 is cut off.

A prototype of LED and its manufacturing process has been constructed with the features of FIGS. 1˜4. The LED and its manufacturing process functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

1-5. (canceled)

6. A LED (light emitting diode) comprising a frame, said frame having a first leg and a second leg, a chip bonded to said first leg, an electrode wire connected between said chip and said second leg of said frame, and a packing material encapsulating said chip and said electrode wire, wherein said packing material comprises a first resin layer, a second resin layer, and a fluorescent layer sandwiched in between said first resin layer and said second resin layer.

7. The LED as claimed in claim 6, wherein said fluorescent layer is evenly sandwiched in between said first resin layer and said second resin layer.

8. The LED as claimed in claim 7, wherein said fluorescent layer is formed of fluorescent materials having different colors including yellow, pink, red, green, and blue.

9. The LED as claimed in claim 8, wherein said fluorescent materials are fluorescent powder.

10. The LED as claimed in claim 8, wherein said fluorescent materials are fluorescent chips.
